(19) United States
(12) Patent Application Publication
(10) Pub. No.: US 2026/0314149 A1
(43) Pub. Date: Oct. 8, 2026

(54) DISPLAY DEVICE INCLUDING BUFFER LAYER, METHOD OF MANUFACTURING THE SAME AND ELECTRONIC DEVICE INCLUDING THE SAME

(71) Applicant: SAMSUNG DISPLAY CO., LTD., YONGIN-SI (KR)

(72) Inventors: In Young JUNG, Yongin-si (KR); Hyune Ok SHIN, Yongin-si (KR); Sung Hoon YANG, Yongin-si (KR)

(21) Appl. No.: 19/629,023

(22) Filed: Mar. 26, 2026

(30) Foreign Application Priority Data
Apr. 2, 2025 (KR) 10-2025-0042713

(51) Int. Cl. H10H 29/856; H10H 20/813; H10H 20/825; H10H 29/01; H10H 29/32; H10H 29/41; H10H 29/80

(52) U.S. Cl. CPC H10H 29/856; H10H 20/8131; H10H 20/825; H10H 29/012; H10H 29/032; H10H 29/32; H10H 29/41; H10H 29/8323

(57) ABSTRACT

A display device includes a circuit stack including a transistor structure, a buffer layer disposed on the circuit stack and including a metal oxide, a via portion penetrating the buffer layer and connected to the transistor structure, an inorganic light-emitting stack disposed on the buffer layer and the via portion, and a transparent electrode disposed on the inorganic light-emitting stack.

### CROSS-REFERENCE TO RELATED APPLICATION

This non-provisional U.S. patent application claims priority to Korean Patent Application No. 10-2025-0042713 filed on Apr. 2, 2025, in the Korean Intellectual Property Office (KIPO), the entire disclosure of which is incorporated by reference herein.

### TECHINICAL FIELD

Embodiments of the present disclosure relate to a display device and, more particularly to, a display device including buffer layer, a method of manufacturing the display device, and an electronic device including the display device.

### DISCUSSION OF THE RELATED ART

With developments of information technologies, a display device capable of displaying information, such as an organic light-emitting diode (OLED) display device, a liquid crystal display (LCD) device, and a field emission display (FED) device, has been developed. In some cases, various flat-panel and flexible display technologies have been introduced.

In some cases, an inorganic light-emitting diode (LED) display having high luminance and enhanced life-span characteristics has been developed. To manufacture the inorganic LED display, high-temperature processes for growing a plurality of inorganic light-emitting layers and inorganic semiconductor layers may be performed, and a transfer process to a pixel circuit may be performed.

### SUMMARY

According to an aspect of the present disclosure, there is provided a display device having improved operational reliability and image efficiency.

According to another aspect of the present disclosure, there is provided a method for manufacturing a display device having improved operational reliability and image efficiency.

According to an aspect of the present disclosure, there is provided an electronic device including a display device having improved operational reliability and image efficiency.

According to embodiments of the present disclosure, a display device includes a circuit stack including a transistor structure, a buffer layer disposed on the circuit stack and including a metal oxide, a via portion penetrating the buffer layer and connected to the transistor structure, an inorganic light-emitting stack disposed on the buffer layer and the via portion, and a transparent electrode disposed on the inorganic light-emitting stack.

In some embodiments, the display device may further include a reflector disposed on the circuit stack, and the buffer layer may cover the reflector.

In some embodiments, the reflector may include a metal, and the buffer layer may include an oxide of the metal included in the reflector.

In some embodiments, the reflector may include aluminum, and the buffer layer may include aluminum oxide.

In some embodiments, the reflector may be spaced apart from the via portion with the buffer layer interposed between the reflector and the via portion.

In some embodiments, the inorganic light-emitting stack may include a first semiconductor layer, an inorganic light-emitting layer, and a second semiconductor layer sequentially stacked on the buffer layer.

In some embodiments, the via portion and the first semiconductor layer may include the same material, and may be integrally formed.

In some embodiments, the first semiconductor layer may include an N-type gallium nitride (GaN), and the second semiconductor layer may include a P-type GaN. The inorganic light-emitting layer may include a first inorganic light-emitting layer including indium gallium nitride (InGaN) and a second inorganic light-emitting layer including GaN.

In some embodiments, the circuit stack may further include a via insulating layer disposed on and covering the transistor structure. An upper side surface of the via portion may be surrounded by the buffer layer, and a lower side surface of the via portion may be surrounded by the via insulating layer.

In some embodiments, the via insulating layer may include a spin-on glass (SOG) layer.

In some embodiments, the display device may further include a spacer. The transistor structure may include a first transistor structure and a second transistor structure. The inorganic light-emitting stack may include a first inorganic light-emitting stack and a second inorganic light-emitting stack connected to the first transistor structure and the second transistor structure, respectively, through the via portion. The spacer may be disposed between the first inorganic light-emitting stack and the second inorganic light-emitting stack.

In some embodiments, the spacer may penetrate the buffer layer and may contact a side surface of the buffer layer.

According to embodiments of the present disclosure, a method for manufacturing a display device includes forming a circuit stack including a transistor structure having a contact electrode, forming a metal layer on the circuit stack, anodizing the metal layer to convert a portion of the metal layer into a buffer layer, forming an inorganic light-emitting stack on the buffer layer, and forming a transparent electrode on the inorganic light-emitting stack.

In some embodiments, the metal layer may be partially etched to form a via hole exposing the contact electrode.

In some embodiments, in forming the inorganic light-emitting stack, a first semiconductor layer, an inorganic light-emitting layer, and a second semiconductor layer may be sequentially formed on the buffer layer. The first semiconductor layer may fill the via hole and may be connected to the contact electrode.

In some embodiments, a remaining portion of the metal layer not anodized is formed as a reflector.

In some embodiments, the inorganic light-emitting stack may be formed by an ion beam sputtering process.

In some embodiments, the metal layer may include aluminum, and the buffer layer may include an aluminum oxide.

According to embodiments of the present disclosure, an electronic device includes a display device, a memory, and a processor configured to execute data included in the memory to control an operation of the display device. The display device includes a circuit stack including a transistor structure, a buffer layer disposed on the circuit stack and including a metal oxide, a via portion penetrating the buffer layer and connected to the transistor structure, an inorganic light-emitting stack disposed on the buffer layer and the via portion, and a transparent electrode disposed on the inorganic light-emitting stack.

In some embodiments, the electronic device may include a virtual reality or augmented reality glass, a smartphone, a tablet PC, a laptop, a TV, a desktop monitor, smart glasses, a head-mounted display, a smart watch, or a vehicle display.

According to embodiments of the present disclosure, an inorganic light-emitting stack may be directly formed on a circuit stack including a transistor structure. Accordingly, a plurality of high-temperature inorganic layer growth processes and transfer processes using a sapphire substrate may be omitted, and thus process efficiency may be improved.

According to embodiments, a front-emission structure having an increased area of a light-emitting region may be implemented using a reflector and a buffer layer formed from the reflector, while sequentially stacking inorganic layers included in the inorganic light-emitting stack.

### BRIEF DESCRIPTION OF THE DRAWINGS

FIG. 1 is a schematic plan view illustrating a pixel arrangement of a display device according to embodiments.

FIG. 2 is a cross-sectional view illustrating a display device according to embodiments.

FIG. 3 is a schematic cross-sectional view illustrating a display device according to some embodiments.

FIG. 4 is a schematic cross-sectional view illustrating a display device according to embodiments.

FIGS. 5, 6, 7, 8, and 9 are schematic cross-sectional views illustrating a method for manufacturing a display device according to embodiments.

FIG. 10 is a block diagram of an electronic device according to an embodiment.

FIG. 11 is a schematic diagram of electronic devices according to embodiments.

### DETAILED DESCRIPTION OF THE EMBODIMENTS

Hereinafter, embodiments of the present disclosure are described in detail with reference to the attached drawings. In the drawings, the same reference numerals are used to indicate the same elements and the drawings. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

The terms "on", "connected", "coupled," etc., used herein refers to a relative placement between elements. For example, a layer, region, or element is referred to as being formed on another layer, region, or element, the layer, region, or element can be directly or indirectly formed on the other layer, region, or element. For example, intervening layers, regions, or elements may be present between the layers, regions, or elements, respectively. As used herein, the term "top surface" may also be referred to as "upper surface."

Terms such as "first," "second," "below," "lower," "above," "upper", etc., are used as a relative sense to distinguish between different elements or positions, and do not designate an absolute position or an absolute order. These terms are used to distinguish one element from another element. For example, a first element discussed below could be termed a second element without departing from the teachings of the present invention. Similarly, the second element could also be termed the first element.

According to embodiments of the present disclosure, a display device may include a buffer layer disposed between a circuit stack and an inorganic light-emitting stack. The buffer layer may be formed by anodizing a metal layer disposed on the circuit stack. The anodizing process may convert exposed regions of the metal layer into a metal-oxide buffer layer. According to embodiments, the buffer layer may be formed directly from the metal layer, so that an oxide structure that may surround a sidewall of a via portion and may enable direct formation of the inorganic light-emitting stack may be formed on the circuit stack. Accordingly, process efficiency may be improved. In some embodiments, a reflector and the anodized buffer layer may be formed from the same metal layer, and a front-emission structure having an increased light-emitting area may be implemented.

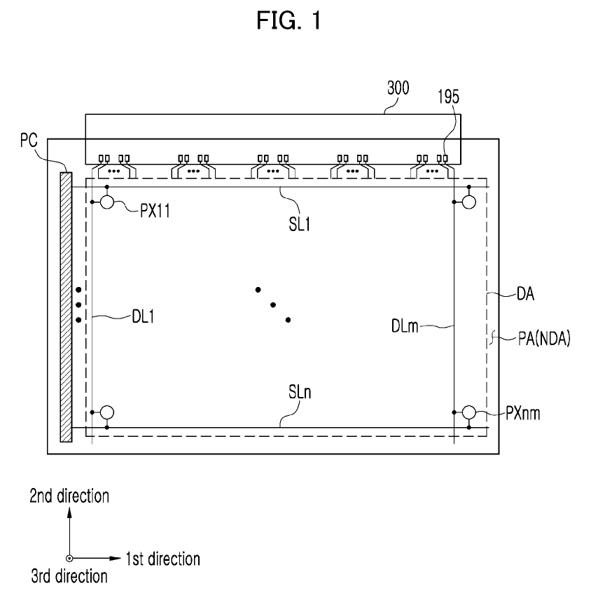

FIG. 1 is a schematic plan view illustrating a pixel arrangement of a display device according to embodiments.

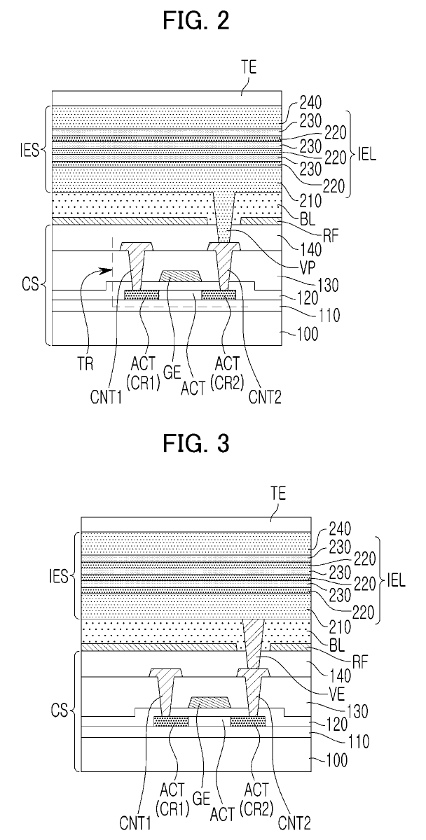

In FIG. 1, a first direction and a second direction may refer to two directions that are parallel to a top surface of a circuit stack CS or a base substrate 100 (see FIG. 2) and cross each other. For example, the first direction and the second direction may be orthogonal to (or crossing) each other.

For example, the first direction may correspond to an X direction (e.g., a row direction or a width direction) of a display device, and the second direction may correspond to a Y direction (a column direction or a length direction) of the display device. A third direction may be perpendicular to the first direction and the second direction. The third direction may correspond to a Z direction (a thickness direction) of the display device. A direction opposite to a direction indicated by an arrow is also regarded as the same direction.

In the accompanying drawings, the above description of the directions may be equally applied to all structural elements, including pixel circuits, interconnection wirings, semiconductor layers, and light-emitting stacks.

Referring to FIG. 1, a circuit stack CS or a base substrate 100 may include a display area DA and a non-display area NDA. A plurality of pixels PX11 to PXnm may be arranged on the display area DA. In some cases, the plurality of pixels PX11 to PXnm may be arranged in a matrix configuration corresponding to intersections between the scan lines SL1 to SLn and the data lines DL1 to DLm. In some embodiments, the non-display area NDA may accommodate peripheral driving circuitry, routing wirings, pad regions, or protection structures.

According to embodiments, a pixel circuit including scan lines (or gate lines) SL1 to SLn forming first to nth rows and data lines DL1 to DLm forming first to mth columns may be arranged on the base substrate 100 of the circuit stack CS. Each of the pixels PX11 to PXnm may be connected to a scan line of a corresponding row among a plurality of the scan lines SL1 to SLn and a data line of a corresponding column among a plurality of the data lines DL1 to DLm.

Each of the pixels PX11 to PXnm may further include a pixel circuit including a transistor and a light-emitting structure. In some cases, the pixel circuit may further include wirings such as a power line, a ground line, an emission control line, or additional signal wirings configured to drive an operation of the light-emitting structure.

Although FIG. 1 illustrates that the data lines DL1 to DLm extend in the second direction and the scan lines SL1 to SLn extend in the first direction, the construction of the pixel circuit is not necessarily limited thereto. Additionally, a shape of each of the pixels PX11 to PXnm is illustrated as a circle in FIG. 1 for convenience of illustration, the shape of each pixel is not necessarily limited thereto. In some cases, each pixel PX may have a rectangular, polygonal, elliptical, or irregular boundary.

A peripheral circuit PC may be disposed in the non-display area NDA that may correspond to a peripheral area of a display area DA. For example, the peripheral circuit PC may include a gate driving circuit. The gate driving circuit may be integrated into the display device through an oxide semiconductor gate (OSG) driving circuit process, an amorphous silicon gate (ASG) driving circuit process, or a polysilicon gate (PSG) driving circuit process. In some embodiments, the peripheral circuit PC may further include compensation circuits, initialization circuits, or other suitable circuits to drive and control the display device.

The peripheral circuit PC may further include a data driver, a gate driver, an emission driver, a power voltage generator, a timing controller, or the like.

The display device may further include a printed circuit board 300. Pads 195 of the pixel circuit may be arranged and grouped on one side portion of the non-display area NDA. The printed circuit board 300 may be electrically connected to the pixel circuit through the pads 195. For example, the printed circuit board 300 may be electrically connected to the pads 195 through a heat-compression process using a conductive intermediate structure such as an anisotropic conductive film (ACF).

An integrated circuit (IC) such as a data driving circuit may be disposed on the printed circuit board 300. In some embodiments, the integrated circuit (IC) chip may be mounted on the printed circuit board 300 in a chip-on-film (COF) form.

FIG. 2 is a cross-sectional view illustrating a display device according to embodiments. FIG. 2 is a cross-sectional view illustrating a circuit structure and a light-emitting structure included in each pixel illustrated in FIG. 1.

Referring to FIG. 2, the display device may include a circuit stack CS and an inorganic light-emitting stack IES stacked on (or disposed on) the circuit stack CS. In some cases, the inorganic light-emitting stack IES may be directly formed on the circuit stack CS through a via portion. In some cases, a buffer layer BL may be disposed between the circuit stack CS and the inorganic light-emitting stack IES.

The circuit stack CS may include the base substrate 100 and a pixel circuit including a transistor structure TR disposed on the base substrate 100. The circuit stack CS may be provided as a backplane structure of a display device configured to drive the inorganic light-emitting stack IES, or may be implemented as a thin-film transistor (TFT) array substrate.

The base substrate 100 may include a glass substrate, a ceramic substrate, or a plastic substrate. According to embodiments, a glass substrate may be used as the base substrate 100 due to the formation of the inorganic light-emitting stack IES. Thus, stability of a deposition process or a film growth process performed at relatively high temperature may be enhanced.

A barrier layer 110 may be formed on a top surface of the base substrate 100. The barrier layer 110 may block moisture, oxygen, or other particles from penetrating through the base substrate 100, and may block diffusion of impurities between the base substrate 100 and a structure formed on the base substrate 100. The barrier layer 110 may be formed entirely over the display area DA and the non-display area NDA of the base substrate 100, and may entirely cover the top surface of the base substrate 100. In some cases, the barrier layer 110 may also provide electrical insulation and surface planarization for subsequent semiconductor and metal deposition steps.

In some cases, for example, the barrier layer 110 may include an inorganic insulating material such as silicon oxide, silicon nitride, silicon oxynitride, or a combination thereof.

In some embodiments, the barrier layer 110 may have a stacked structure including a silicon oxide layer and a silicon nitride layer. The barrier layer 110 may be formed to include the above-described inorganic insulating material using a deposition process such as a chemical vapor deposition (CVD) process, a sputtering process, an atomic layer deposition (ALD) process, or other deposition processes.

In some embodiments, the barrier layer 110 may include an organic layer, and may have a multi-layered structure of an organic layer and an inorganic layer.

The pixel circuit may include wirings including the scan lines and the data lines described with reference to FIG. 1, and a transistor structure TR that may electrically interact with the wirings. The transistor structure TR may be electrically connected to a first semiconductor layer 210 of the inorganic light-emitting stack IES.

The transistor structure TR may include an active layer ACT, a gate insulating layer 120, and a gate electrode GE. The transistor structure TR may further include contact electrodes CNT1 and CNT2.

The active layer ACT may be disposed on the barrier layer 110 and may be patterned, for example, using a photo-lithography process to be arranged repeatedly and regularly for each pixel. The active layer ACT may include a silicon compound such as polysilicon or amorphous silicon. Portions of the active layer ACT may be doped with a p-type dopant or an n-type dopant so that the active layer ACT may include a source region, a drain region, and a channel region. In an embodiment, the active layer ACT may be patterned to include multiple channel regions configured to support multi-gate driving.

The active layer ACT may include an oxide semiconductor such as indium gallium zinc oxide (IGZO), zinc tin oxide (ZTO), or indium tin zinc oxide (ITZO).

The gate insulating layer 120 may be formed on the active layer ACT, and the gate electrode GE may be stacked on the gate insulating layer 120. As illustrated in FIG. 2, the gate insulating layer 120 may continuously extend to cover both the barrier layer 110 and the active layer ACT to provide electrical isolation and to reduce leakage current between adjacent pixel circuits.

In an embodiment, the gate insulating layer 120 may partially cover each active layer 110, and may be formed as an independent pattern in each of the transistor structures TR.

The gate electrode GE may overlap the channel region of the active layer ACT in the third direction. A scan signal may be transmitted from the scan line through the gate electrode GE.

The gate insulating layer 120 may be formed through a deposition process to include an inorganic insulating material such as silicon oxide, silicon nitride, silicon oxynitride, a metal oxide, or other dielectric materials. In an embodiment, the gate insulating layer 120 may include a multi-layer stacked dielectric structure.

In some embodiments, a p-type dopant or an n-type dopant may be implanted into the active layer ACT by an ion-implantation process using the gate electrode GE as an ion-implantation mask. Accordingly, a first contact region CR1 and a second contact region CR2 may be formed at one side portion and the other side portion of the active layer ACT, respectively. The first contact region CR1 and the second contact region CR2 may correspond to the source region and the drain region, respectively.

A portion of the active layer ACT that may overlap the gate electrode GE in a vertical direction (the third direction) between the first contact region CR1 and the second contact region CR2 may be defined as the channel region.

In some embodiments, the gate insulating layer 120 may be formed in a pattern covering the channel region by an etching process using the gate electrode GE as an etching mask. When the active layer ACT includes an oxide semiconductor, hydrogen (H) included in an insulating interlayer 130 may be diffused or moved into the active layer ACT while forming the insulating interlayer 130. Accordingly, a carrier concentration may be increased by hydrogen, and thus the contact regions CR1 and CR2 may be formed at side portions of the active layer ACT.

The insulating interlayer 130 covering the gate insulating layer 120 and the gate electrode GE may be formed on the active layer ACT. For example, the insulating interlayer 130 may cover an upper surface of the gate insulating layer 120, and an upper surface and side surfaces of the gate electrode GE. The insulating interlayer 130 may be formed by a deposition process to include an inorganic insulating material such as silicon oxide, silicon nitride, silicon oxynitride, or other dielectric materials. The insulating interlayer 130 may be formed in a single-layered structure or a multi-layered structure including different materials.

The contact electrodes CNT1 and CNT2 contacting or electrically connected to the active layer ACT may be formed on the insulating interlayer 130 through corresponding contact holes extending to the first contact region CR1 and the second contact region CR2, respectively.

The contact electrode may include a first contact electrode CNT1 connected to or in contact with the first contact region CR1 of the active layer ACT, and a second contact electrode CNT2 connected to or in contact with the second contact region CR2 of the active layer ACT. In some embodiments, the first contact electrode CNT1 and the second contact electrode CNT2 may be provided as a source electrode and a drain electrode, respectively.

According to some embodiments, contact holes may be formed by partially etching the insulating interlayer 130. For example, the contact holes that respectively expose the first contact region CR1 and the second contact region CR2 may be formed. The contact holes may also extend through the gate insulating layer 120.

After forming a metal layer on the insulating interlayer 130 to fill the contact holes, the metal layer may be partially etched to form the first contact electrode CNT1 and the second contact electrode CNT2. For example, a data signal may be transmitted from the data line through the first contact electrode CNT1.

The gate electrode GE and the contact electrodes CNT1 and CNT2 may include a metal such as silver (Ag), magnesium (Mg), aluminum (Al), tungsten (W), copper (Cu), nickel (Ni), chromium (Cr), molybdenum (Mo), titanium (Ti), platinum (Pt), tantalum (Ta), neodymium (Nd), scandium (Sc), an alloy thereof, or a nitride thereof. The gate electrode GE and the contact electrodes CNT1 and CNT2 may be formed by a deposition process such as a sputtering process. In an embodiment, the gate electrode GE may include a multilayer stack including different metal or metal layers).

The gate electrode GE and the contact electrodes CNT1 and CNT2 may be formed to have a multi-layered structure (e.g., a titanium (Ti) layer, an aluminum (Al) layer, and a titanium (Ti) layer). For example, an uppermost portion of the contact electrodes CNT1 and CNT2 may include the Ti layer, and may promote growth of a first semiconductor layer 210 from the contact electrodes CNT1 and CNT2.

A via insulating layer 140 covering the contact electrodes CNT1 and CNT2 may be formed on the insulating interlayer 130. The via insulating layer 140 may serve as a planarization layer of the circuit stack CS or the thin-film transistor (TFT) array and may further provide lateral electrical isolation between adjacent transistor structures TR.

In some embodiments, the via insulating layer 140 may include a silicate material formed using an organic silane-based material or an organic siloxane-based material. In an embodiment, the via insulating layer 140 may be formed of a spin-on glass (SOG) layer.

A reflector RF and a buffer layer BL may be formed on the circuit stack CS or the via insulating layer 140. The reflector RF may be disposed on a top surface of the via insulating layer 140, and the buffer layer BL may cover the reflector RF on the via insulating layer 140. According to embodiments, the buffer layer BL may completely cover a top surface and a side surface of the reflector RF.

The reflector RF may include a metal. A front-emitting structure in which light is emitted over a transparent electrode TE may be implemented by the reflector RF. According to embodiments, the reflector RF may include aluminum or an aluminum alloy.

The buffer layer BL may be formed of an insulator, and may include a metal oxide. The buffer layer BL may include an oxide of the same metal as that included in the reflector RF. According to embodiments, the buffer layer BL may include aluminum oxide (e.g., Al₂O₃). In some cases, a portion of the buffer layer BL may be disposed between two adjacent reflectors RF disposed on the insulating layer 140.

As described below, the buffer layer BL may be formed by anodizing a metal layer used for forming the reflector RF. For example, an exposed portion (e.g., an upper surface) of the metal layer may be electrochemically converted into a metal oxide. During the anodizing process, the upper surface and sidewall regions of the metal layer may be oxidized to form a conformal oxide layer.

The inorganic light-emitting stack IES may be disposed on the buffer layer BL. The inorganic light-emitting stack IES may cover the transistor structure TR included in the circuit stack CS on the buffer layer BL. For example, the inorganic light-emitting stack IES may overlap the transistor structure TR on the buffer layer BL in the third direction.

The inorganic light-emitting stack IES may include the first semiconductor layer 210, a second semiconductor layer 240, and an inorganic light-emitting layer IEL disposed between the first semiconductor layer 210 and the second semiconductor layer 240. In one aspect, the inorganic light-emitting layer IEL includes a first inorganic light-emitting layer 220 and a second inorganic light-emitting layer 230 alternately stacked.

According to embodiments, the first semiconductor layer 210 may be an N-type Gallium nitride (GaN) layer. The first semiconductor layer 210 may include GaN including an N-type dopant (e.g., Si, P and/or As). The second semiconductor layer 240 may be a P-type GaN layer. The second semiconductor layer 240 may include GaN including a P-type dopant (e.g., Mg, B and/or BF).

According to embodiments of the present disclosure, the first semiconductor layer 210 may be electrically connected to the transistor structure TR through a via portion VP. In some embodiments, the first semiconductor layer 210 may be electrically connected to the second contact electrode CNT2 of the transistor structure TR through the via portion VP.

The via portion VP may penetrate the buffer layer BL and in contact with or connected to a top surface of the second contact electrode CNT2. The via portion VP may also penetrate at least a portion of the via insulating layer 140.

A side surface of the via portion VP may be surrounded by the buffer layer BL. In some cases, the side surface of the via portion VP may be surrounded by the via insulating layer 140. The reflector RF may be physically separated and spaced apart from the via portion VP with the buffer layer BL disposed therebetween.

For example, an upper side surface of the via portion VP may be surrounded by the buffer layer BL, and a lower side surface of the via portion VP may be surrounded by the via insulating layer 140.

According to embodiments, the via portion VP may include the same material as the material of the first semiconductor layer 210, and may be a single member substantially integrally connected with the first semiconductor layer 210. Accordingly, the via portion VP may also include the N-type GaN. In some cases, the via portion VP may be formed to have a tapered profile that improves step coverage during deposition of the first semiconductor layer 210 on to the buffer layer BL and a portion of the upper surface of the second contact electrode CNT2.

The inorganic light-emitting layer IEL may have a multi-layer structure including a first inorganic light-emitting layer 220 and a second inorganic light-emitting layer 230. For example, the first inorganic light-emitting layer 220 and the second inorganic light-emitting layer 230 may be alternately and repeatedly stacked on the first semiconductor layer 210. The inorganic light-emitting layer IEL may be formed as a quantum well layer.

The first inorganic light-emitting layer 220 may include Indium Gallium Nitride (InGaN). The second inorganic light-emitting layer 230 may include GaN. A thickness of the first inorganic light-emitting layer 220 may be smaller than a thickness of the second inorganic light-emitting layer 230. For example, the thickness of the first inorganic light-emitting layer 220 may range from 1 nm to 9 nm, or from 1 nm to 5 nm, and the thickness of the second inorganic light-emitting layer 230 may range from 10 nm to 20 nm, or from 10 nm to 15 nm.

In some embodiments, a thickness of the first semiconductor layer 210 (excluding the via portion (VP)) may range from 1 µm to 5 µm, or 1 µm to 4 µm. A thickness of the second semiconductor layer 240 may range from 100 nm to 300 nm, or from 100 nm to 200 nm.

The transparent electrode TE may be stacked on the inorganic light-emitting stack IES. The transparent electrode TE may serve as a common electrode for a plurality of pixels included in the display device, and may function as a cathode.

The transparent electrode TE may include a transparent conductive oxide such as indium tin oxide (ITO), indium zinc oxide (IZO), zinc oxide (ZnO), indium tin zinc oxide (ITZO), or other transparent conductive oxides.

According to some embodiments, the layers included in the inorganic light-emitting stack IES may be stably formed using the buffer layer BL, and the inorganic light-emitting stack IES may be connected to the transistor structure TR through the via portion VP. Additionally, a front-emission structure may be implemented using the reflector RF spaced apart from the via portion VP.

Accordingly, the layers of the inorganic light-emitting stack IES may be stacked to overlap the transistor structure TR. Thus, a sufficient light-emitting area may be achieved while minimizing an aperture ratio due to a space of the transistor structure TR.

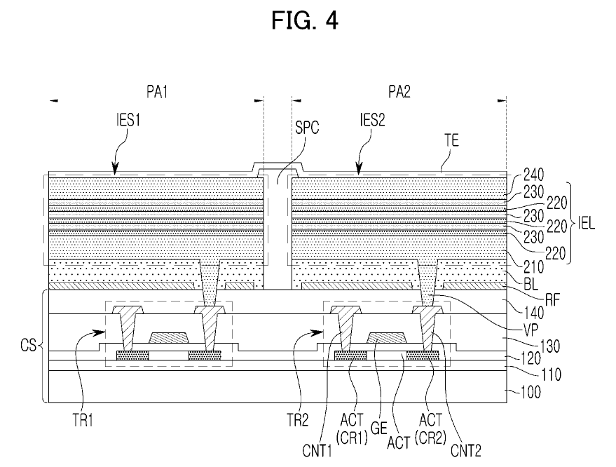

FIG. 3 is a schematic cross-sectional view illustrating a display device according to some embodiments. Detailed descriptions of structures and elements substantially the same as or similar to those described with reference to FIG. 2 might not be described and the differences may be described.

Referring to FIG. 3, the via portion VP may be included as a separate component including a material different from the material of the first semiconductor layer 210. According to embodiments, the via portion VP may be formed as a via electrode VE including titanium Ti. In some cases, the via electrode VE may be positioned to extend through the buffer layer BL and the via insulating layer 140. In some cases, the via electrode VE may electrically connect the first semiconductor layer 210 and the second contact electrode CNT2 of the transistor structure TR.

Accordingly, application of voltage or transfer of current from the second contact electrode CNT2 to the first semiconductor layer 210 may be facilitated through the via electrode VE. Additionally, the Ti layer included in the via electrode VE may have a hexagonal crystal structure together with aluminum oxide included in the buffer layer BL. Thus, a top surface of the via electrode VE may promote growth or deposition of the inorganic light-emitting stack IES together with the buffer layer BL.

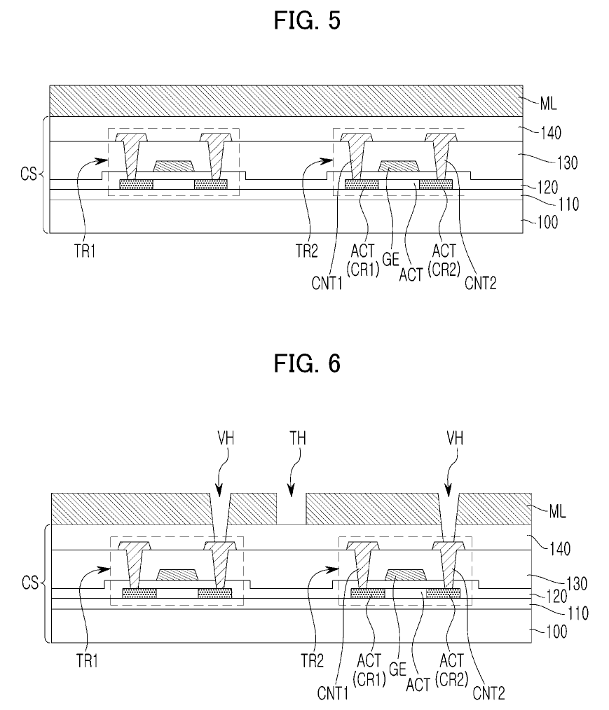

FIG. 4 is a schematic cross-sectional view illustrating a display device according to embodiments. Detailed descriptions of structures and elements substantially the same as or similar to those described with reference to FIG. 2 might not be described and the differences may be described.

Referring to FIG. 4, the display device may further include a spacer SPC configured to separate the inorganic light-emitting stacks IES included in different pixels.

According to embodiments, the display device may include a first pixel area PA1 and a second pixel area PA2 adjacent to each other. The first pixel area PA1 may include a first transistor structure TR1 and a first inorganic light-emitting stack IES1 disposed on the first transistor structure TR1. The reflector RF and the buffer layer BL may be disposed between the first inorganic light-emitting stack IES1 and the first transistor structure TR1, and the first inorganic light-emitting stack IES1 may be connected to the first transistor structure TR1 through the via portion VP penetrating the buffer layer BL and the via insulating layer 140.

The second pixel area PA2 may include a second transistor structure TR2 and a second inorganic light-emitting stack IES2 disposed on the second transistor structure TR2. The reflector RF and the buffer layer BL may be disposed between the second inorganic light-emitting stack IES2 and the second transistor structure TR2, and the second inorganic light-emitting stack IES2 may be connected to the second transistor structure TR2 through the via portion VP penetrating the buffer layer BL and the via insulating layer 140.

The spacer SPC may be disposed between the first inorganic light-emitting stack IES1 and the second inorganic light-emitting stack IES2, and may be disposed on the circuit stack CS or the via insulating layer 140. Accordingly, the first inorganic light-emitting stack IES1 and the second inorganic light-emitting stack IES2 may be separated by the spacer SPC. In some cases, the first pixel area PA1 and the second pixel area PA2 may be substantially separated or defined by the spacer SPC to reduce optical and electrical crosstalk.

The spacer SPC may be disposed between the buffer layers BL included in the first pixel area PA1 and the second pixel area PA2. For example, the buffer layer BL disposed on the first pixel area PA1 and the second pixel area PA2 may be disconnected by spacer SPC. Accordingly, the buffer layers BL included in the first pixel area PA1 and the second pixel area PA2 may also be substantially separated by the spacer SPC.

In some embodiments, an upper side surface of the spacer SPC may surround the side surfaces of the inorganic light-emitting stack IES included in each pixel area. A lower side surface of the spacer SPC may surround the side surfaces of the buffer layer BL included in each pixel area.

The spacer SPC may be separated or spaced apart from the reflector RF with the buffer layer BL interposed therebetween. For example, the lower side surface of the spacer SPC might not be in contact with the side surface of the reflector RF.

The spacer SPC may include an organic insulating material such as an acrylic-based resin, an epoxy-based resin, a urethane-based resin, a siloxane-based resin, or other suitable resins.

The transparent electrode TE may continuously extend along top surfaces of the plurality of the inorganic light-emitting stacks IES and a top surface of the spacer SPC. For example, the transparent electrode TE may cover upper surfaces of the first inorganic light-emitting stack IES1, the spacer SPC, and the second inorganic light-emitting stack IES2. In some cases, the via insulating layer 140 may continuously extend along the first pixel area PA1, the spacer SPC, and the second pixel area PA2.

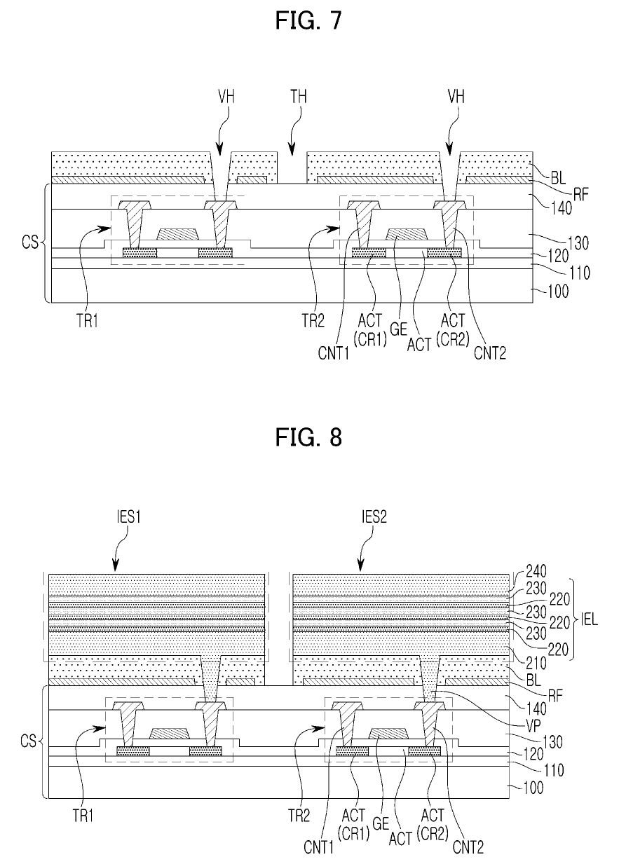

FIGS. 5 to 9 are schematic cross-sectional views illustrating a method for manufacturing a display device according to embodiments. Detailed descriptions of materials substantially the same as or similar to those described with reference to FIG. 3 might not be described and the differences may be further described.

Referring to FIG. 5, as described with reference to FIG. 2, the transistor structure TR may be formed on the base substrate 100. According to embodiments, the barrier layer 110 may be formed on the base substrate 100, and the first transistor structure TR1 and the second transistor structure TR2 may be formed on the barrier layer 110. Then, the gate insulating layer 120 may be formed on the active layer ACT of the first and second transistor structures TR1 and TR2. Then, the insulating interlayer 130 may be formed on the gate insulating layer 120 and gate electrode GE of the first and second transistor structures TR1 and TR2.

Thereafter, the via insulating layer 140 covering the first transistor structure TR1 and the second transistor structure TR2 may be formed on the insulating interlayer 130 to form the circuit stack CS. As described above, the via insulating layer 140 may be formed to include a silicate material substantially similar to glass through a crystallization through a heat treatment after coating an organic siloxane-based material or an organic silane-based material. According to embodiments, the via insulating layer 140 may be formed as a spin-on glass (SOG) layer. In some cases, the via insulating layer 140 may be substantially planar and covers the gate insulating layer 120 and the insulating interlayer 130.

A metal layer ML may be formed on the via insulating layer 140. According to embodiments, the metal layer ML may include aluminum, and may be formed using a deposition process such as a sputtering process.

Referring to FIG. 6, the metal layer ML and the via insulating layer 140 may be etched by a photo-lithography process to form the via holes VH. The via holes VH may expose the top surface of each of the second contact electrodes CNT2 included in the first transistor structure TR1 and the second transistor structure TR2 and may define openings through which a via portion is subsequently formed.

In some embodiments, a trench TH may be formed by partially etching the metal layer ML. For example, the trench TH may be formed by etching a portion of the metal layer ML formed on a portion of the via insulating layer 140 between the first transistor structure TR1 and the second transistor structure TR2.

In some embodiments, a top surface of the via insulating layer 140 may be exposed by the trench TH.

Referring to FIG. 7, the metal layer ML may be anodized to convert a portion of the metal layer ML into the buffer layer BL including aluminum oxide (Al₂O₃) while leaving a remaining portion of the metal layer ML that is not anodized to function as the reflector RF.

According to embodiments, aluminum may be anodized using an electrolyte solution that may include an organic acid such as tartaric acid. In some embodiments, the anodizing treatment may be performed at a pH in a range from 6 to 8, from 6.5 to 7.5, or from 6.5 to 7, and at a temperature of 20 °C to 30 °C or at room temperature.

As described above, an exposed portion of the metal layer ML may be partially converted into the buffer layer BL by performing the anodizing under relatively mild conditions. For example, the metal layer ML may be converted into the buffer layer BL in which the anodizing voltage, pH, and temperature are controlled to limit oxidation to the exposed regions of the metal layer ML.

An upper portion of the metal layer ML, and side portions of the metal layer ML exposed on sidewalls of the via hole VH and the trench TH may be oxidized and converted into the buffer layer BL by the anodizing process. A portion of the metal layer ML that is not converted into the buffer layer BL may remain as the reflector RF.

Referring to FIG. 8, the inorganic light-emitting stack IES may be formed on the buffer layer BL. A first inorganic light-emitting stack IES1 may be formed on the buffer layer BL that is formed on the first transistor structure TR1, and the second inorganic light-emitting stack IES2 may be formed on the buffer layer BL that is formed on the second transistor structure TR2 so that each inorganic light-emitting stack is aligned with the corresponding via portion VP and the corresponding transistor structure TR.

The buffer layer BL may include aluminum oxide having a hexagonal crystal structure, and thus the first semiconductor layer 210 including a GaN-based material may be efficiently deposited or grown.

The first semiconductor layer 210 may also fill the via hole VH so that the via portion VP contacting and connected to the second contact electrode CNT2 may be formed . According to embodiments, an upper portion of the second contact electrode CNT2 may include a Ti layer. The Ti layer may have a hexagonal crystal structure, and may promote the growth of the first semiconductor layer 210 together with the buffer layer BL.

In some embodiments, as described with reference to FIG. 3, the via electrode VE including Ti may be first formed in the via hole VH, and then the first semiconductor layer 210 may be formed on the buffer layer BL and the via electrode VE.

According to embodiments, the first semiconductor layer 210 may be formed to include an N-type GaN.

The first inorganic light-emitting layer 220 including InGaN and the second inorganic light-emitting layer 230 including GaN may be alternately formed on the first semiconductor layer 210 to form the inorganic light-emitting layer IEL. The second semiconductor layer 240 including a P-type GaN may be formed on the inorganic light-emitting layer IEL to form the first inorganic light-emitting stack IES1 and the second inorganic light-emitting stack IES2. In some cases, each of the first inorganic light-emitting stack IES1 and the second inorganic light-emitting stack IES2 may include the first semiconductor layer 210, the inorganic light-emitting layer IEL, and the second semiconductor layer 240 sequentially disposed.

As described above, the first inorganic light-emitting stack IES1 and the second inorganic light-emitting stack IES2 may have an inorganic light-emitting diode structure connected to the first transistor structure TR1 and the second transistor structure TR2, respectively, through the via portion VP (or the via electrode VE).

According to embodiments, each of the layers included in the first inorganic light-emitting stack IES1 and the second inorganic light-emitting stack IES2 may be formed by an ion beam sputtering process in which the buffer layer BL may be used as a growth promoting layer. Accordingly, a temperature for the deposition of each inorganic light-emitting layer may be lowered relative to conventional manufacturing process.

In some embodiments, the temperature for the growth or the deposition of each inorganic light-emitting layer included in the first inorganic light-emitting stack IES1 and the second inorganic light-emitting stack IES2 may be less than 600 °C, less than or equal to 500 °C, or less than or equal to 400 °C. For example, the temperature for the growth or the deposition may range from 200 °C to 500 °C, or from 300 °C to 400 °C.

The inorganic light-emitting stack IES may be formed at a relatively low temperature, so that an additional growth process using a sapphire substrate and a subsequent transfer process to a circuit board (a TFT substrate) may be eliminated. Accordingly, the inorganic light-emitting stack IES may be directly formed on the circuit stack CS.

Further, the via insulating layer 140 substantially having a glass-like structure may be formed under the buffer layer BL to further enhance thermal stability of the circuit stack CS.

Referring to FIG. 9, the spacer SPC may be formed between the first inorganic light-emitting stack IES1 and the second inorganic light-emitting stack IES2. For example, the spacer SPC may fill a region formed between the first inorganic light-emitting stack IES1 and the second inorganic light-emitting stack IES2, and on the via insulating layer 140.

According to embodiments, a spacer layer may be formed by filling a space between the first inorganic light-emitting stack IES1 and the second inorganic light-emitting stack IES2 with an organic insulating material by a spin coating process, an inkjet process, or other suitable processes. The spacer layer may also fill the trench TH (see FIG. 7) between the adjacent buffer layers BL. The spacer layer may also be formed on a portion of the top surfaces of the first inorganic light-emitting stack IES1 and the second inorganic light-emitting stack IES2.

Subsequently, a portion of the spacer layer formed on the top surfaces of the first inorganic light-emitting stack IES1 and the second inorganic light-emitting stack IES2 may be partially etched to form the spacer SPC.

The transparent electrode TE may be formed on the top surfaces of the first inorganic light-emitting stack IES1 and the second inorganic light-emitting stack IES2, and on a top surface of the spacer SPC. The transparent electrode TE may be formed to include the above-described transparent conductive oxide by a deposition process such as a sputtering process.

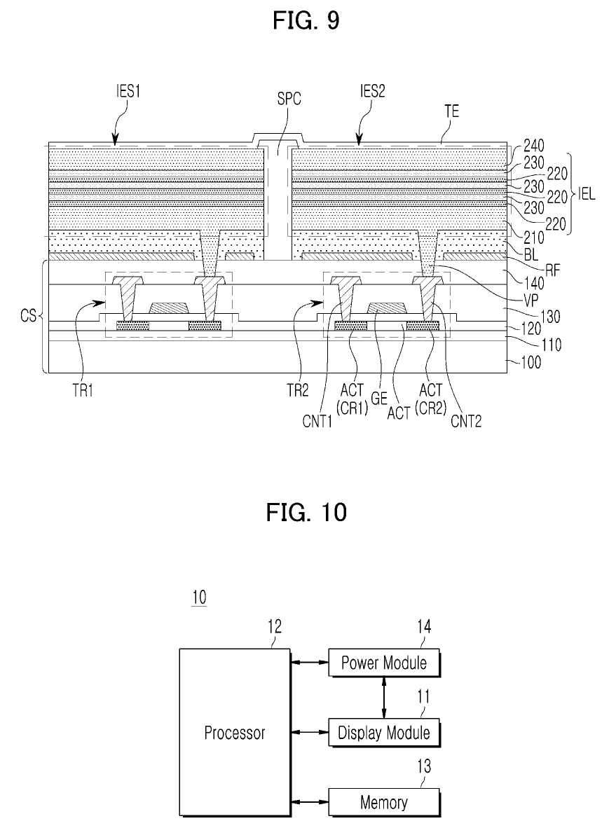

FIG. 10 is a block diagram of an electronic device according to one embodiment.

Referring to FIG. 10, an electronic device may include a display module 11, a processor 12, a memory 13, and a power module 14.

The processor 12 may include a central processing unit (CPU), an application processor (AP), a graphics processing unit (GPU), a communication processor (CP), an image signal processor (ISP), and/or a controller. In some cases, the processor 12 may control the overall operation of the electronic device 10, including driving the display module 11 based on image and data signals stored in memory 13. The power module 14 may supply and control electrical power provided to each of the functional components.

The memory 13 may store data for operating the processor 12 or the display module 11. When the processor 12 executes an application stored in the memory 13, a video (or image) data signal and/or an input control signal may be transmitted to the display module 11, and the display module 11 may process the received signal and output video information through a display screen of the display module 11.

The power module 14 may include a power supply module such as a power adapter or a battery device, and a power conversion module that converts power to operate the electronic device 10.

At least one of the components of the above-described electronic device 10 may be included in a display device. Additionally, some of the individual modules functionally included in one module may be included in the display device, and other modules may be provided separately from the display device. For example, the display module 11 may include the display device, and the processor 12, the memory 13 and the power module 14 may be included in additional devices within the electronic device 10, other than the display device.

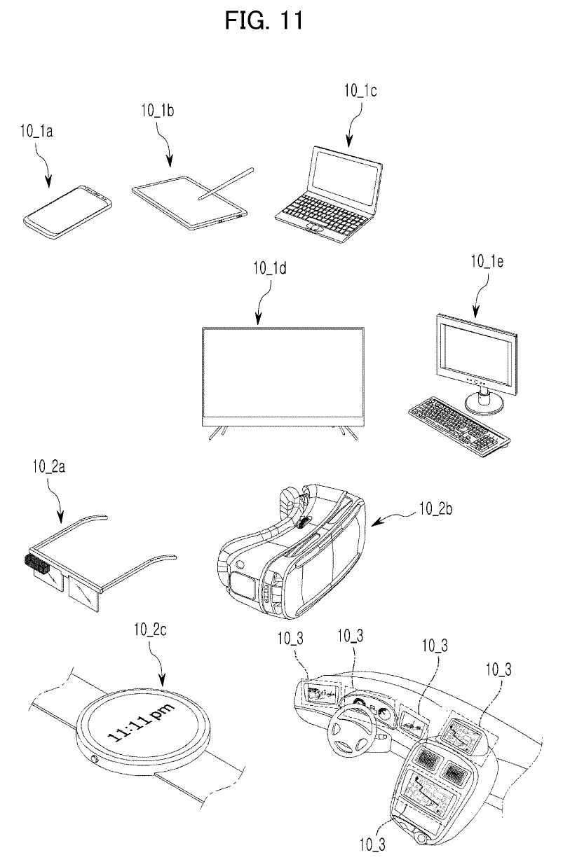

FIG. 11 is a schematic diagram of an electronic device according to exemplary embodiments.

Referring to FIG. 11, non-limiting examples of various electronic devices to which the display device is applied may include an electronic device for image display such as a smartphone 10_1a, a tablet computer 10_1b, a laptop computer 10_1c, a television (TV) 10_1d, and a desktop monitor 10_1e; a wearable electronic device including a display module such as smart glasses 10_2a, a head-mounted display 10_2b, and a smart watch 10_2c; and an electronic device for a vehicle 10_3 including a display module such as a center information display (CID) disposed on an instrument panel, a center fascia, or a dashboard of a vehicle, a head-up display, a room mirror display. The electronic device may also include virtual reality glasses or augmented reality glasses.

In the detailed description, those skilled in the art will appreciate that many variations and modifications can be made to the preferred embodiments without substantially departing from the technical scope and principles of the present inventive concept. Therefore, the disclosed preferred embodiments of the invention are used in a generic and descriptive sense.

What is claimed is:

1. A display device, comprising:
a circuit stack including a transistor structure;
a buffer layer disposed on the circuit stack, wherein the buffer layer includes a metal oxide;
a via portion penetrating the buffer layer and connected to the transistor structure;
an inorganic light-emitting stack disposed on the buffer layer and the via portion; and
a transparent electrode disposed on the inorganic light-emitting stack.

2. The display device of claim 1, further comprising:
a reflector disposed on the circuit stack, wherein the buffer layer covers the reflector.

3. The display device of claim 2, wherein:
the reflector includes a metal, and the buffer layer includes an oxide of the metal included in the reflector.

4. The display device of claim 3, wherein:
the reflector includes aluminum, and the buffer layer includes aluminum oxide.

5. The display device of claim 2, wherein:
the reflector is spaced apart from the via portion with the buffer layer interposed between the reflector and the via portion.

6. The display device of claim 1, wherein:
the inorganic light-emitting stack includes a first semiconductor layer, an inorganic light-emitting layer, and a second semiconductor layer sequentially stacked on the buffer layer.

7. The display device of claim 6, wherein:
the via portion and the first semiconductor layer include the same material, and are integrally formed.

8. The display device of claim 6, wherein:
the first semiconductor layer includes an N-type gallium nitride (GaN), and the second semiconductor layer includes a P-type GaN; and
the inorganic light-emitting layer includes a first inorganic light-emitting layer including indium gallium nitride (InGaN) and a second inorganic light-emitting layer including GaN.

9. The display device of claim 1, wherein the circuit stack further comprises:
a via insulating layer disposed on and covering the transistor structure, and
an upper side surface of the via portion is surrounded by the buffer layer, and a lower side surface of the via portion is surrounded by the via insulating layer.

10. The display device of claim 9, wherein:
the via insulating layer includes a spin-on glass (SOG) layer.

11. The display device of claim 1, further comprising a spacer,
wherein the transistor structure comprises a first transistor structure and a second transistor structure,
the inorganic light-emitting stack comprises a first inorganic light-emitting stack and a second inorganic light-emitting stack connected to the first transistor structure and the second transistor structure, respectively, through the via portion, and
the spacer is disposed between the first inorganic light-emitting stack and the second inorganic light-emitting stack.

12. The display device of claim 11, wherein:
the spacer penetrates the buffer layer, and contacts a side surface of the buffer layer.

13. A method for manufacturing a display device, comprising:
forming a circuit stack including a transistor structure having a contact electrode;
forming a metal layer on the circuit stack;
anodizing the metal layer to convert a portion of the metal layer into a buffer layer;
forming an inorganic light-emitting stack on the buffer layer; and
forming a transparent electrode on the inorganic light-emitting stack.

14. The method of claim 13, further comprising:
partially etching the metal layer to form a via hole to expose the contact electrode.

15. The method of claim 14, wherein forming the inorganic light-emitting stack comprises:
forming a first semiconductor layer, an inorganic light-emitting layer, and a second semiconductor layer sequentially on the buffer layer,
wherein the first semiconductor layer fills the via hole and is connected to the contact electrode.

16. The method of claim 13, wherein:
a remaining portion of the metal layer not anodized is formed as a reflector.

17. The method of claim 13, wherein forming the inorganic light-emitting stack comprises:
performing an ion beam sputtering process.

18. The method of claim 13, wherein:
the metal layer includes aluminum, and the buffer layer includes aluminum oxide.

19. An electronic device, comprising:
a display device;
a memory; and
a processor configured to execute data included in the memory to control an operation of the display device,
wherein the display device comprises:
a circuit stack including a transistor structure;
a buffer layer disposed on the circuit stack, wherein the buffer layer includes a metal oxide;
a via portion penetrating the buffer layer and connected to the transistor structure;
an inorganic light-emitting stack disposed on the buffer layer and the via portion; and
a transparent electrode disposed on the inorganic light-emitting stack.

20. The electronic device of claim 19, wherein the electronic device includes
virtual reality or augmented reality glasses, a smartphone, a tablet PC, a laptop, a television, a desktop monitor, smart glasses, a head-mounted display, a smart watch, or a vehicle display.
